(19) United States
(12) Patent Application Publication
(10) Pub. No.: US 2024/0038579 A1
(43) Pub. Date: Feb. 1, 2024

(54) DIE SIZE REDUCTION AND DEEP TRENCH DENSITY INCREASE USING DEEP TRENCH ISOLATION AFTER SHALLOW TRENCH ISOLATION INTEGRATION

(71) Applicant: Texas Instruments Incorporated, Dallas, TX (US)

(72) Inventors: Asad Haider, Plano, TX (US); Hao Yang, Allen, TX (US); Guruvayurappan Mathur, Allen, TX (US); Alexei Sadovnikov, Sunnyvale, CA (US); Abbas Ali, Plano, TX (US); Umamaheswari Aghoram, Richardson, TX (US)

(21) Appl. No.: 17/877,964

(22) Filed: Jul. 31, 2022

(51) Int. Cl. H01L 21/762; H01L 29/06

(52) U.S. Cl. CPC H01L 21/76229; H01L 29/0623

(57) ABSTRACT

An electronic device includes a semiconductor substrate and a semiconductor surface layer having a first conductivity type, as well as a buried layer, a deep trench structure and a shallow trench isolation structure, the semiconductor surface layer over the semiconductor substrate and having a top surface, the buried layer having an opposite second conductivity type between the semiconductor surface layer and the semiconductor substrate, the deep trench structure including a trench that extends through the semiconductor surface layer and into the buried layer, a dielectric liner on a sidewall of the trench from the semiconductor surface layer to the buried layer, and polysilicon that extends on the dielectric liner and fills the trench to the side of the semiconductor surface layer, the shallow trench isolation structure extends into the semiconductor surface layer, and the shallow trench isolation structure in contact with the deep trench structure.

### CROSS REFERENCE TO RELATED APPLICATIONS

This application is related to application serial no. xx/xxx,xxx, (Texas Instruments Docket No. T101712US01, “LOCOS OR SIBLK TO PROTECT DEEP TRENCH POLYSILICON IN DEEP TRENCH AFTER STI PROCESS”, by Yang, et al.), filed on even date herewith and incorporated herein by reference in its entirety.

### BACKGROUND

Isolation structures separate electrically circuits of different power supply domains and/or types, such as high and low voltage circuits or analog and digital circuits in an integrated circuit. Shallow trench isolation (STI) is a type of isolation structure with dielectric material deposited into shallow trenches etched between circuit areas to be laterally isolated. Deep trench isolation (DTI) is used to mitigate electric current leakage between adjacent semiconductor device components. Die size reduction is desired for smaller form factor electronic device and/or increased circuit density in electronic devices.

### SUMMARY

In one aspect, An electronic device includes a semiconductor substrate and a semiconductor surface layer having a first conductivity type, as well as a buried layer, a deep trench structure and a shallow trench isolation structure, the semiconductor surface layer over the semiconductor substrate and having a top surface, the buried layer having an opposite second conductivity type between the semiconductor surface layer and the semiconductor substrate, the deep trench structure including a trench that extends through the semiconductor surface layer and into the buried layer, a dielectric liner on a sidewall of the trench from the semiconductor surface layer to the buried layer, and polysilicon that extends on the dielectric liner and fills the trench to the side of the semiconductor surface layer, the shallow trench isolation structure extends into the semiconductor surface layer, and the shallow trench isolation structure in contact with the deep trench structure.

In another aspect, an electronic device includes a semiconductor substrate having a first conductivity type, a semiconductor surface layer over the semiconductor substrate and having the first conductivity type, a buried layer having an opposite second conductivity type between the semiconductor surface layer and the semiconductor substrate, a shallow trench isolation structure that extends into the semiconductor surface layer, and a deep trench structure that extends through the shallow trench isolation structure, through the semiconductor surface layer, and into the buried layer, a top surface of the deep trench structure extending above a top surface of the shallow trench isolation structure.

In a further aspect, a method of fabricating an electronic device includes forming a shallow trench isolation structure that extends into a semiconductor surface layer and forming a deep trench structure through the shallow trench isolation structure, through the semiconductor surface layer, and into a buried layer.

### BRIEF DESCRIPTION OF THE DRAWINGS

FIG. 1 is a partial sectional side elevation view of an electronic device that includes a deep trench structure formed through shallow trench isolation.

FIG. 1A is a sectional side elevation view of the electronic device of FIG. 1 including a package structure.

FIGS. 1B and 1C show detail views of portions of FIG. 1.

FIG. 2 is a flow diagram of a method for making an electronic device and for making a deep trench structure in an electronic device.

FIGS. 3-28 are partial sectional side elevation views of the electronic device of FIG. 1 at various stages of fabrication according to the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating.

STI thermal processing can laterally diffuse deep doped region dopants, which inhibits the ability to reduce and control the spacing between DTI isolation structures and transistors, resistors and other component structures in a semiconductor die.

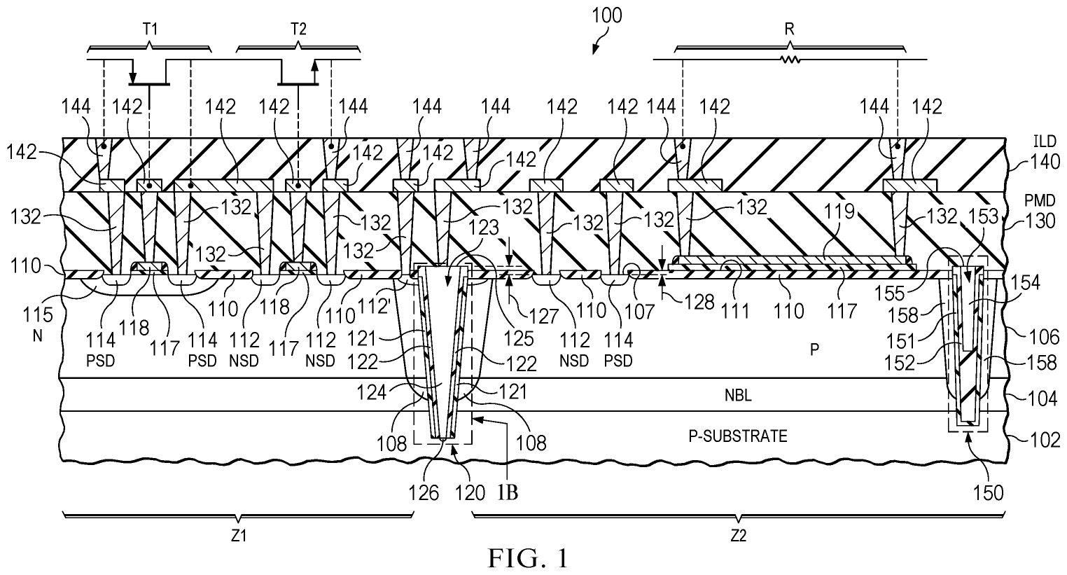

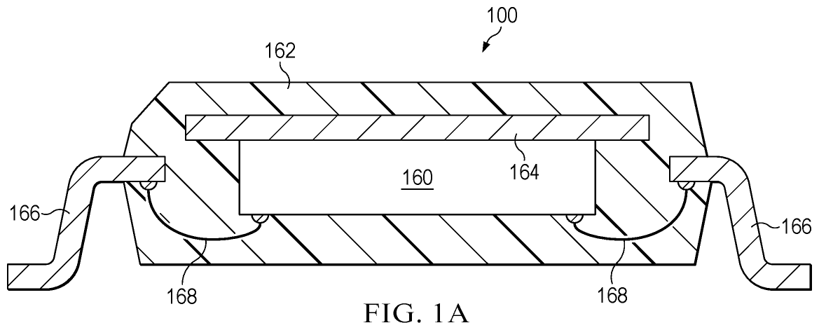

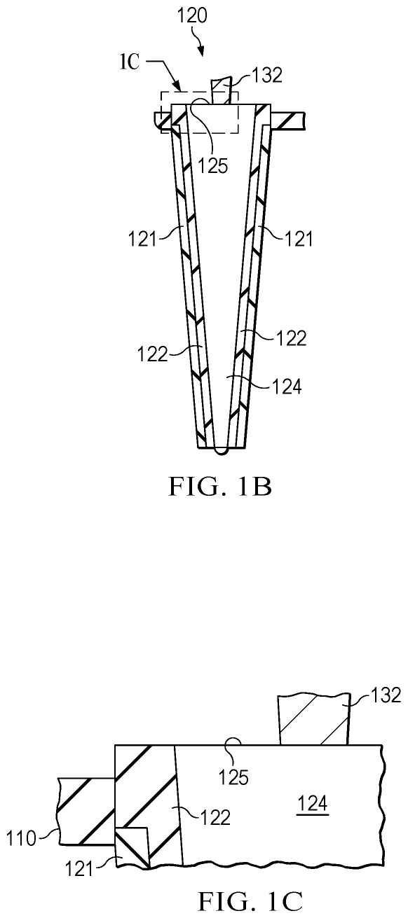

FIGS. 1 and 1A show an electronic device 100 that includes a deep trench structure formed through a shallow trench isolation (STI) layer. As used herein the term “shallow trench isolation” refers to an oxide or other electrically insulating material (e.g., having a thickness in nm or greater) that is deposited or otherwise formed in a trench in a semiconductor surface layer for shallow trench isolation. The deep trench structure can be a deep trench isolation structure (DTI), or a top side contact (TSC) structure or implementations can include both DTI and TSC structures. The use of a shallow trench isolation structure provides benefits including providing or enhancing isolation around a deep trench structure. The deep trench structure facilitates electrical isolation between components or circuits, such as narrow DTI structures, and/or facilitates top side electrical connection to a device substrate using a wider TSC deep trench structure. The described examples include deep trench structures formed after the STI structures, with deep doped regions formed after STI processing to mitigate lateral diffusion of deep dopants and facilitate reduced lateral extent of the deep trench structure and deep doped regions and allow closer spacing transistors, resistors and other component structures in a semiconductor die. This benefit facilitates increased circuit density and/or reduced device size for improved electronic devices. The electronic device 100 in FIGS. 1 and 1A includes a deep trench structure formed through an STI structure, with a top side of the deep trench structure extending above a top side of the STI structure, and with a deep doped region surrounding a portion of the deep trench structure and having a lateral extent that is unaffected by the creation of the STI structure. The decoupling of the deep doped region lateral size facilitates advanced designs with reduced circuit size and/or increased circuit density. The electronic device 100 includes STI structures formed before the deep trench structures and before the deep doped region that at least partially surrounds the deep trench structure.

The electronic device 100 in one example is an integrated circuit product, only a portion of which is shown in FIG. 1. The electronic device 100 includes electronic components, such as transistors, resistors, capacitors fabricated on or in a semiconductor structure of a starting wafer, which is subsequently separated or singulated into individual semiconductor dies that are separately packaged to produce integrated circuit products. The electronic device 100 includes a semiconductor structure having a semiconductor substrate 102 (e.g., labeled “P-SUBSTRATE” in FIG. 1) and a buried layer 104 (e.g., labeled “NBL”) in a portion of the semiconductor substrate 102. The electronic device 100 also includes a semiconductor surface layer 106 (e.g., labeled “P”) with an upper or top side 107, as well as a deep doped region 108.

The electronic device 100 includes a dielectric isolation layer 110 that includes portions that may be contiguous or noncontiguous. In the illustrated example the dielectric isolation layer 110 is implemented as contiguous or noncontiguous shallow trench isolation (STI) structures. Other examples may implement the dielectric isolation layer 110 using contiguous or noncontiguous local oxidation of silicon (LOCOS) structures. The following discussion refers to examples in which the dielectric isolation layer 110 is implemented with STI structures without implied limitation thereto, and may refer to the dielectric isolation layer 110 as STI structures 110.

The STI structures 110 have upper or top surfaces 111 and extend into trenches in corresponding portions of the top side 107 of the semiconductor surface layer 106. In one example, the STI structures 110 are or includes silicon dioxide (SiO2). The semiconductor substrate 102 in one example is a silicon or silicon on insulator (SOI) structure that includes majority carrier dopants of a first conductivity type. The buried layer 104 extends in a portion of the semiconductor substrate 102 and includes majority carrier dopants of an opposite second conductivity type. In the illustrated implementation, the first conductivity type is P, the second conductivity type is N, the semiconductor substrate 102 is labeled “P”, and the buried layer 104 is an N-type buried layer labeled “NBL” in the drawings. In another implementation (not shown), the first conductivity type is N, and the second conductivity type is P. The semiconductor substrate 102 in one example includes a base silicon or silicon-on-insulator (SOI) wafer with an epitaxial silicon layer formed thereon. In one example, the buried layer 104 is implanted into a top side of the starting silicon or SOI wafer, and the semiconductor surface layer 106 is an epitaxial silicon layer formed over the buried layer 104.

The semiconductor surface layer 106 in the illustrated example is or includes epitaxial silicon having majority carrier dopants of the first conductivity type and is labeled “P” in the drawings. The deep doped region 108 includes majority carrier dopants of the second conductivity type (e.g., a deep N region). The deep doped region 108 extends from the semiconductor surface layer 106 into the buried layer 104. In another example, the deep doped region 108 extends through the buried layer 104 and into the semiconductor substrate 102. In the illustrated example, the deep doped region 108 extends from the semiconductor surface layer 106 partially into the buried layer 104 and does not extend into the underlying semiconductor substrate 102.

A first implanted region 112 (e.g., a first portion) of the semiconductor surface layer 106 along the top side 107 includes majority carrier dopants of the second conductivity type and is labeled “NSD” in the drawings. A second portion or implanted region 114 of the semiconductor surface layer 106 along the top side 107 includes majority carrier dopants of the first conductivity type and is labeled “PSD” in the drawings. A third portion 116 (e.g., a third implanted region) of the semiconductor surface layer 106 within the deep doped region 108 along the top side 107 includes majority carrier dopants of the second conductivity type and is labeled “NSD” in the drawings. While the top side 107 is shown in the present example as the top surface of the second implanted region 114, for this purpose of this description and the claims the top side 107 includes the top surface of the semiconductor surface layer 106 and other implanted regions such as the first implanted region 112 and second implanted region 114.

The electronic device 100 includes a first field effect transistor (FET) T1, and a second FET T2 formed on and/or in the semiconductor surface layer 106. The first transistor T1 is a p-channel FET with p-doped source/drains formed by corresponding second implanted regions, or source/drain implanted regions 114, within an n-doped region 115 in an upper portion of the semiconductor surface layer 106. The second transistor T2 is an n-channel FET with corresponding first implanted regions, or source/drain implanted regions 112, forming source/drains of the transistor T2. The transistors T1 and T2 include corresponding gate oxide or gate dielectric structures 117 formed over channel regions between the source/drain implanted regions 112, 114, as well as polysilicon gate electrodes 118 extending on the corresponding gate dielectric structures 117 spaced apart and above the respective transistor channel regions. The electronic device 100 also includes a polysilicon resistor R, including a gate dielectric structure 117 formed over a portion of one of the STI structures 110, as well as a polysilicon resistor structure 119 formed above the gate dielectric structure 117 of the resistor R.

The electronic device 100 includes a wide first deep trench structure 120 (e.g., a DTI or TSC structure) that provides a top side electrical contact to the semiconductor substrate 102 between a first zone Z1 and a second zone Z2, as well as a second, narrower deep trench structure 150 (e.g., a deep trench isolation or DTI structure) that provides electrical isolation. Some aspects of the first deep trench structure 120 are shown in greater detail in FIGS. 1B and 1C. In the illustrated example, the first and second transistors T1 and T2 are formed in the first zone Z1, and the resistor R is formed in the second zone Z2. The deep trench structure 120 includes a first dielectric liner 121 on a sidewall of a trench 123, and a second dielectric liner 122 on the first dielectric liner 121. The first and second dielectric liners 121, 122 may be referred to together as a bilayer dielectric liner. In one example, the first dielectric liner 121 is or includes a thermally grown silicon dioxide (SiO₂) of any suitable stoichiometry and thickness, and the second dielectric liner 122 is or includes a deposited silicon oxide (SiOₓ) of any suitable stoichiometry and thickness. The first dielectric liner 121 may merge with the STI structure 110 abutting the deep trench structure 120, resulting in a continuous material layer as illustrated in FIG. 1C.

The deep doped region 108 surrounds the deep trench structure 120. In another implementation, a single layer dielectric liner (not shown) is formed along the trench sidewall. In another implementation, a multilayer dielectric liner (not shown) includes more than two dielectric layers along the trench sidewall. The trench 123 is filled with doped polysilicon 124. A top surface 125 of the deep trench structure 120 includes the topmost surface of the polysilicon 124 and the topmost surface of the second dielectric liner 122. (See FIG. 1C.) The top surface 125 may be, and in the current example is shown as being, higher than the top surface 111 of the STI structure 110. The doped polysilicon 124 may be referred to herein as a “core” or “first core”. The trench 123 extends through the semiconductor surface layer 106 to the semiconductor substrate 102. In this implementation, the deep trench structure 120 extends through the semiconductor surface layer 106, through opposite upper and lower sides of the buried layer 104 and into the underlying semiconductor substrate 102. In another implementation, the deep trench structure 120 extends into the buried layer 104 but does not extend into the underlying semiconductor substrate 102. An implanted contact 126 to the semiconductor substrate 102 under the trench 123 includes majority carrier dopants of the first conductivity type. The bilayer dielectric liner 121, 122 extends on the sidewall of the trench 123 from the semiconductor surface layer 106 on the sidewall of the trench 123 from the semiconductor surface layer 106 to the buried layer 104 and into the semiconductor substrate 102. The bilayer dielectric liner 121, 122 conductively isolates the polysilicon 124 from the semiconductor surface layer 106.

The polysilicon 124 includes majority carrier dopants of the first conductivity type. The polysilicon 124 extends on the dielectric liner 122 and fills the trench 123 to above the top side 107 of the semiconductor surface layer 106. In the example of FIG. 1, the trench 123, the dielectric liner 122, and the polysilicon 124 extend beyond the top side 107 of the semiconductor surface layer 106 through a portion of the STI structure 110. A portion (e.g., side) of the STI structure 110 contacts (e.g., touches) a portion of the deep trench structure 120. The top surface 125 of the polysilicon 124 extends upward beyond the top side 107 of the semiconductor surface layer 106 by a first distance 127, and the top surface 111 of the STI structure 110 extends upward beyond the top side 107 of the semiconductor surface layer 106 by a second distance 128.

The deep trench structure 120 and a narrower deep trench structure 150 in the electronic device 100 of FIG. 1 are fabricated after formation (e.g., growth or deposition) of the STI structure 110, and the first distance 127 is greater than the second distance 128 in the electronic device 100 of FIG. 1 (e.g., the polysilicon 124 extends upward past and above the top surface 111 of the STI structure 110 in the configuration and orientation shown in FIG. 1). In one example, the deep trench structure 120 extends in two dimensions to laterally encircle or surround one or both of the zones Z1 and/or Z2, and the electronic device 100 can have any suitable number of isolated zones (not shown) surrounded by similar deep trench structures 120. The electronic device 100 can include any number of electronic circuit components, such as transistors (e.g., T1 and T2), resistors (e.g., resistor R), capacitors, diodes, etc. (not shown) interconnected to form electrical circuits in one or more isolated regions, and the circuits of two or more isolated regions can be interconnected, for example, through openings in the deep trench structure or structures and/or by metallization routing interconnections.

The electronic device 100 includes a multilevel metallization structure, a portion of which is shown in FIG. 1. The electronic device 100 includes a first dielectric layer 130 (e.g., a pre-metal dielectric layer labeled “PMD” in FIG. 1) that extends on or over the STI structures 110 and portions of the top side 107 of the semiconductor surface layer 106 and over the top of the deep trench structure 120. In one example, the first dielectric (PMD) layer 130 is or includes SiO2. The PMD layer 130 includes conductive contacts 132 that extend through the PMD layer 130 to form electrical contacts to the respective source/drain implanted regions 112 and 114 of the semiconductor surface layer 106. The PMD layer 130 also includes a conductive contact 132 that forms an electrical (ohmic) contact to the top surface 125 of the doped polysilicon 124 of the deep trench structure 120, as well as a separate conductive contact 132 that forms an electrical contact to a first implanted region 112′ that encircles the top of the deep trench structure 120 in the deep doped region 108 as shown in FIG. 1. In one example, the conductive contacts 132 are or include tungsten.

The multilevel metallization structure in this example also includes a second (e.g., interlayer or interlevel) dielectric layer 140 (e.g., SiOₓ), which is labeled “ILD” in FIG. 1. The second dielectric layer 140 includes conductive routing structures 142, such as traces or lines. In one example, the conductive routing structures 142 are or include copper or aluminum or aluminum or other conductive metal. The second dielectric layer 140 includes conductive vias 144 that are or include copper or aluminum or other conductive metal. In one example, the electronic device 100 includes one or more further metallization layers or levels (not shown).

The electronic device 100 also includes a narrower second deep trench structure 150 having a bilayer liner 151 and 152 along the bottom and sidewalls of a second trench 153 for deep trench isolation (DTI). In one example, the first dielectric liner 151 is or includes a thermally grown silicon dioxide (SiO₂) of any suitable stoichiometry and thickness, and the second dielectric liner layer 152 is or includes a deposited silicon oxide (SiOₓ) of any suitable stoichiometry and thickness. The second deep trench structure 150 includes polysilicon 154 that may also be referred to herein as a core or “second core”. The second deep trench structure 150 is laterally narrower than the first deep trench structure 120 and the polysilicon 154 is shallower than the first polysilicon 124 due to the narrower second trench 153 and can be electrically floating with respect to one or more circuits of the electronic device and/or the substrate 102. The second trench 153 in the example of FIG. 1 is filled with the polysilicon 154 with an upper or top surface 155. A portion of the second deep trench structure 150 is surrounded by a second deep doped region 158 having majority carriers of the N type (e.g., phosphorous). The second deep trench structure 150 extends through a second portion of the STI structure 110, through the semiconductor surface layer 106, and into the buried layer 104. The top surface 155 of the second deep trench structure 150 extends above the top surface 111 of the second portion of the associated STI structure 110 by the distance 127. The second deep trench structure 150 facilitates electrically floating isolation during operation of the electronic device 100. Various disclosed devices and methods of the present disclosure may be beneficially applied for circuit isolation using STI and narrow or floating deep trench structures such as the respective structures 120 and 150 in FIG. 1. While such embodiments may be expected to provide improvements in performance relative to baseline implementations, no particular result is a requirement unless explicitly recited in a particular claim.

As further shown in FIG. 1A, the finished electronic device 100 includes a package structure having a semiconductor die 160 enclosed in a molded package 162. In the illustrated example, the semiconductor die 160 is mounted on a conductive metal die attach pad 164, and conductive bond pads of the die 160 are electrically coupled to respective leads 166 via conductive bond wires 168 to form electrical connections to external circuitry, for example, of a printed circuit board (PCB, not shown) to which the packaged electronic device 100 is attached.

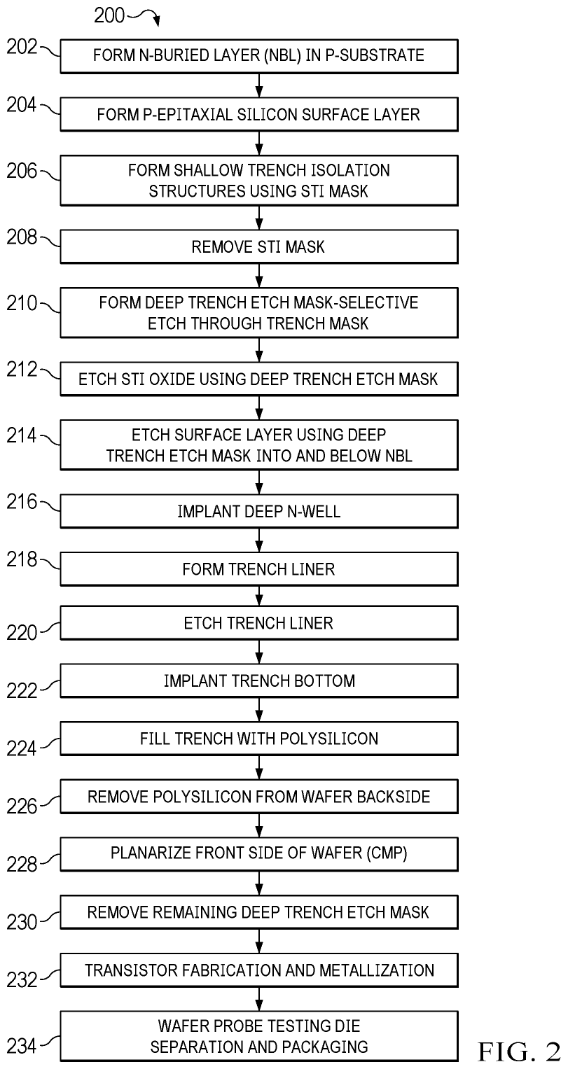

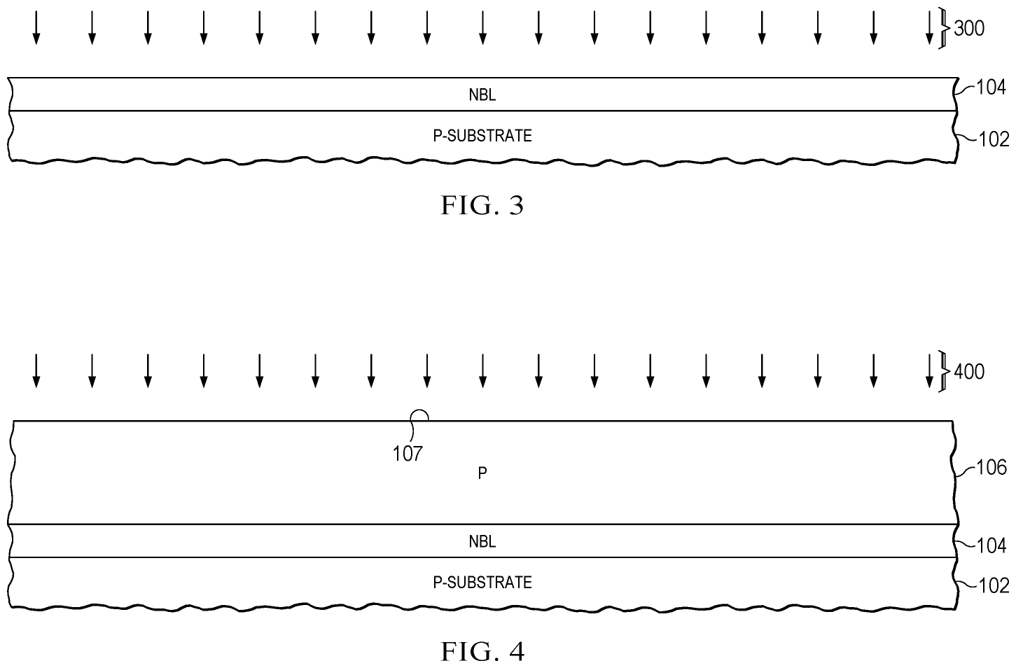

Referring also to FIGS. 2-28, FIG. 2 shows a method 200 for making an electronic device and for making a deep trench structure in an electronic device. FIGS. 3-28 show the electronic device 100 of FIG. 1 at various stages of fabrication according to the method 200. The method 200 includes forming an STI structure that extends into a portion of a side of a semiconductor surface layer as well as and forming a deep trench structure through a portion of the STI structure, through the semiconductor surface layer 106, and into a buried layer 104. The method 200 begins with a starting substrate 102, such as a silicon wafer or a silicon on insulator wafer that includes majority carrier dopants of a first conductivity type (e.g., P in the illustrated example), or on a starting wafer that includes another semiconductor material.

The method 200 includes forming a buried layer at 202. FIG. 3 shows one example, in which an implantation process 300 is performed, such as a blanket implant or a selective implant using an implant mask (not shown). The implantation process 300 implants dopants of the second conductivity type (e.g., N in the illustrated example) into an exposed portion of the top side of the semiconductor substrate 102 to form the buried layer 104 in a portion of the semiconductor substrate 102.

At 204 in FIG. 2, the method 200 also includes forming a semiconductor surface layer on the semiconductor substrate. FIG. 4 shows one example, in which an epitaxial growth process 400 is performed with in-situ P-type dopants that grows the P-doped epitaxial silicon semiconductor surface layer 106 on the top side of the semiconductor substrate 102. The semiconductor surface layer 106 has a top side 107 as previously described.

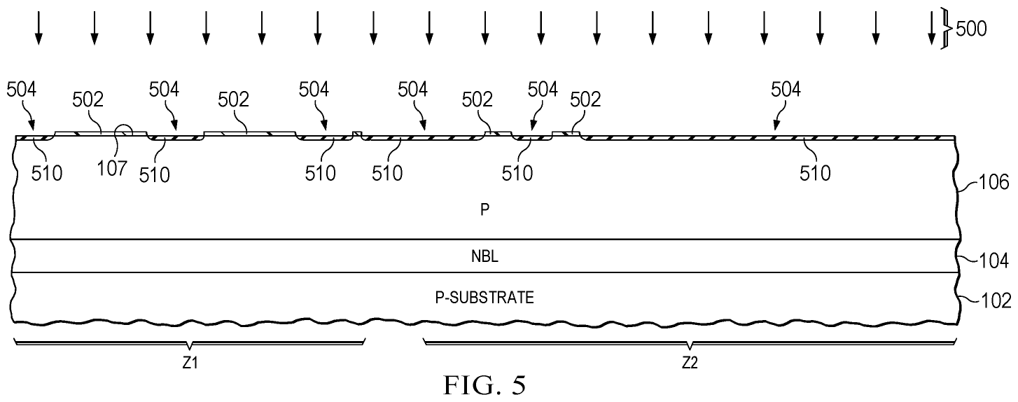

At 206 in FIG. 2, the method 200 also includes forming one or more shallow trench isolation structures, for example, by etching a trench and filling the trench with oxide or other suitable electrically isolating material. FIGS. 5-9 show one example, in which a trench etch process 500 is performed using a nitride or other suitable trench etch mask 502. The etch process 500 forms STI trenches 504 in select portions of the top side 107 of the semiconductor surface layer 106.

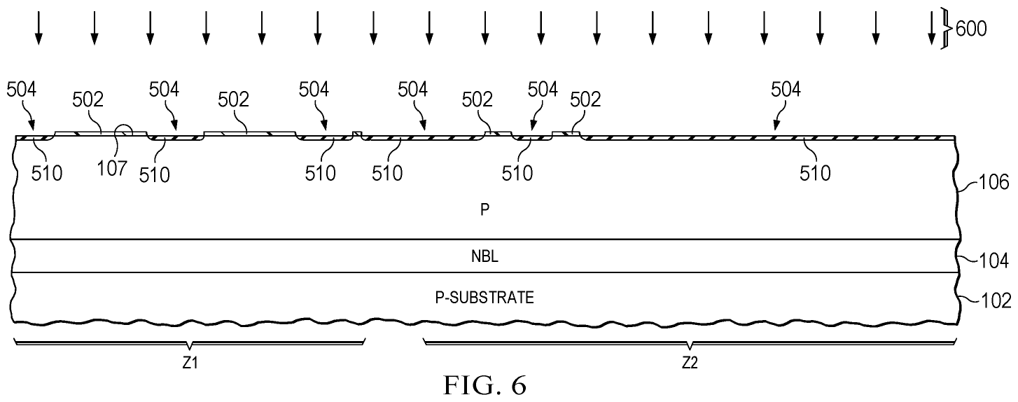

The STI structure formation at 206 in one example also includes oxidizing the exposed bottoms and sidewalls of the STI trenches 504. FIG. 6 shows one example, in which an oxidation process 600 is performed that exposes the processed wafer to an oxidizing environment with the trench etch mask 502 in place so that the exposed bottoms and sidewalls of the trenches 504 are oxidized.

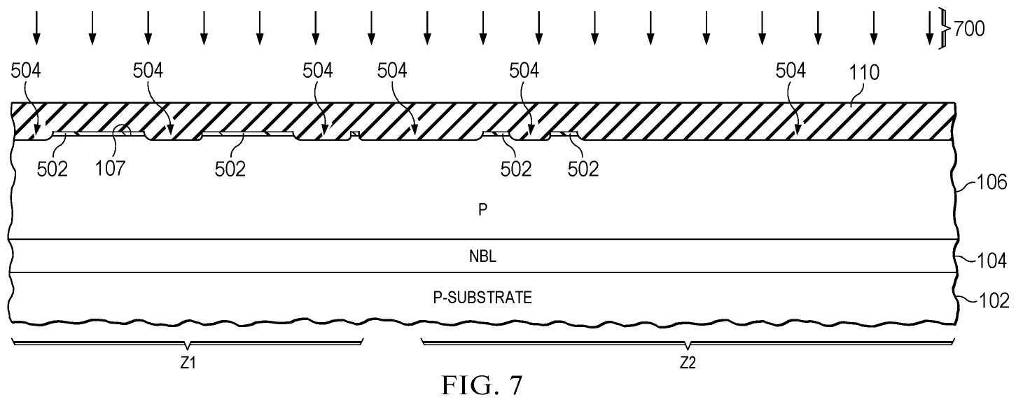

The STI processing at 206 also includes filling the trenches 504 with silicon dioxide or other suitable STI material. FIG. 7 shows one example, in which a deposition process 700 is performed that deposits silicon dioxide to fill the trenches 504, and the deposition is continued until the sides and tops of the trench etch mask 502 material are covered with an oxide layer.

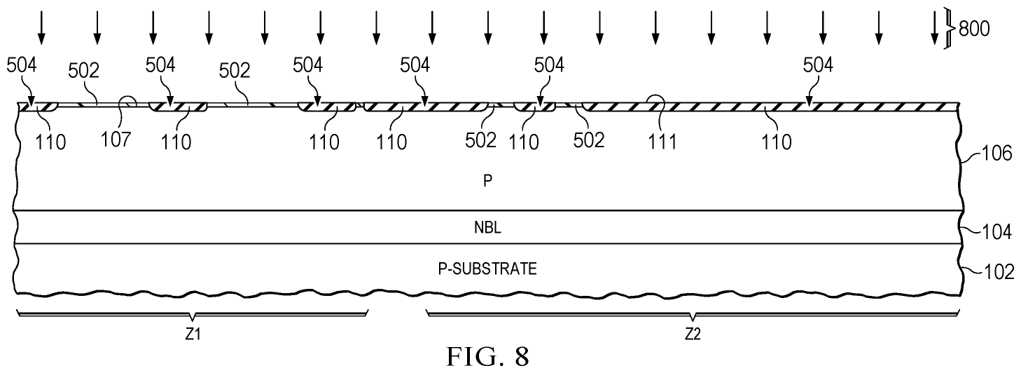

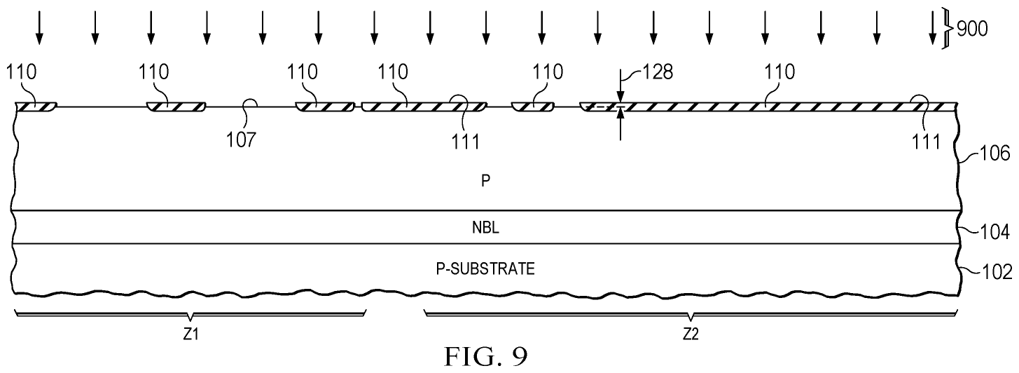

A planarization is then performed to planarize the top side of the processed wafer. FIG. 8 shows one example, in which a chemical mechanical polishing (CMP) process 800 is performed that removes portions of the deposited oxide material , leaving the finished STI structures 110 with generally planar top surfaces, and the process 800 exposes the STI trench etch mask 502. The method 200 continues at 208 with removing the STI trench etch mask 502. FIG. 9 shows an example, in which a stripping process 900 is performed that removes the STI trench etch mask 502 and leaves the patterned STI structures 110 having respective top surface 111 that extend above the top side 107 of the semiconductor surface layer 106 by the distance 128.

The method 200 continues at 210, 212, and 214 in FIG. 2 with forming one or more deep trench structures (e.g., the wide top side contact or TSC deep trench structure 120 and the narrower deep trench structure 150 that provides deep trench isolation (DTI) as described above). FIGS. show an example deep trench implementation that includes forming a dielectric trench etch mask at 210, etching through a portion of the STI structure 110 using the mask at 212, and etching through the semiconductor surface layer 106 and into the semiconductor substrate 102 at 214. In another implementation, for example, in which a blanket implantation was used to form the buried layer 104, the second etch at 214 forms the trench partially into the buried layer 104.

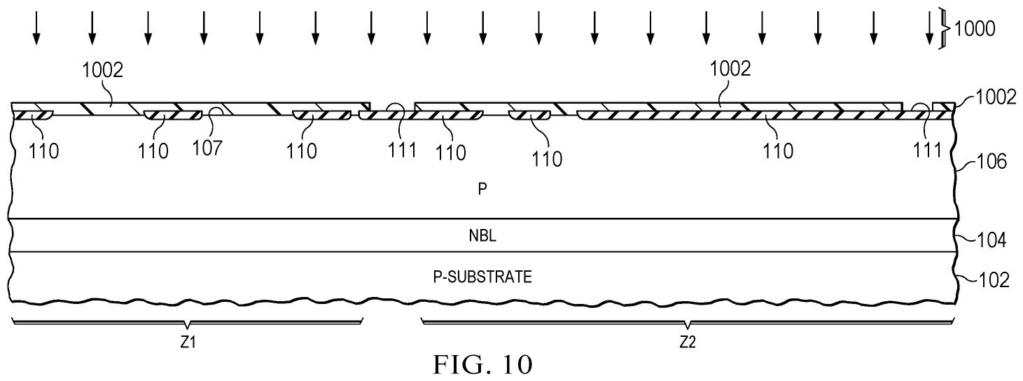

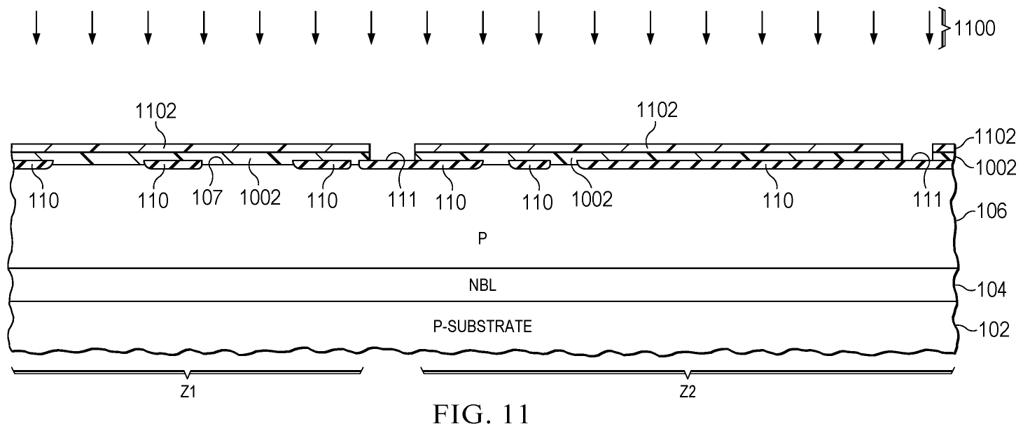

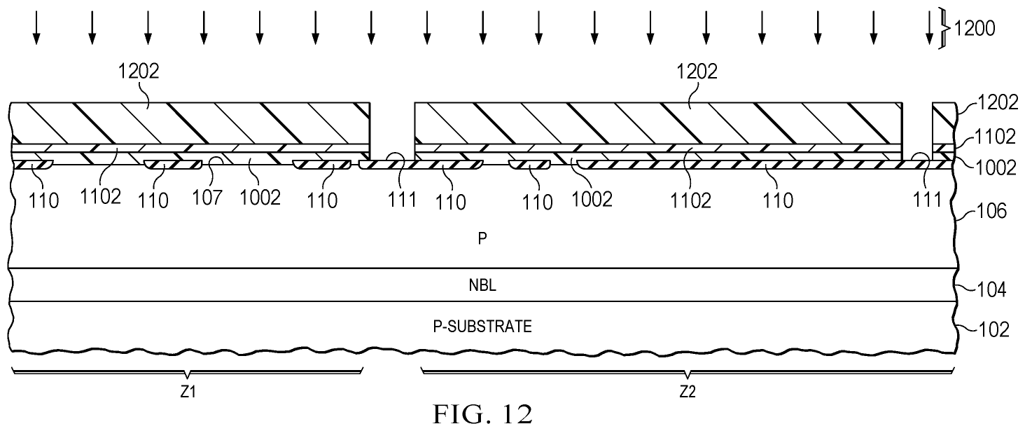

FIGS. 10-12 show an example of the trench etch mask formation at 210, in which a patterned multilayer etch mask is created. The nominal layer thicknesses and composition of the trench etch mask layers are adjustable depending on the depth of the isolation trench and vary within manufacturing tolerances. In other example, more or fewer layers are used in forming the trench etch mask at 210. In the illustrated implementation, a process 1000 is performed in FIG. 10 that deposits and patterns a silicon dioxide trench etch mask 1002 to expose first and second portions of the STI structure 110. In one example, the silicon dioxide layer 1002 has a thickness of 15 nm. In FIG. 11, a process 1100 is performed that deposits (e.g., by chemical vapor deposition) and patterns a silicon nitride trench etch mask 1102, for example, to a thickness of 200 nm. In FIG. 12, a process 1200 is performed that deposits and patterns another silicon dioxide trench etch mask 1202, for example, to a thickness of 1.4 μm to complete the patterned multilayer dielectric etch mask 1002, 1102, 1202 with openings that expose first and second prospective deep trench locations along the top surface 111 of respective ones of the STI structures 110.

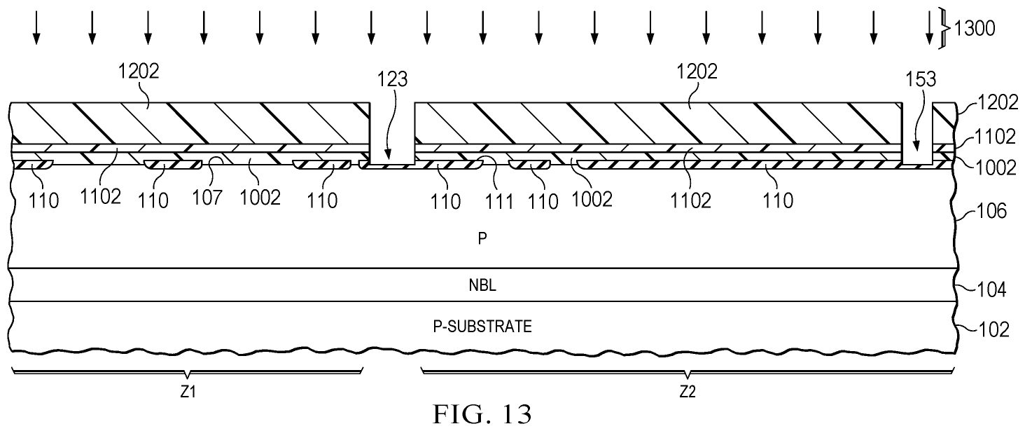

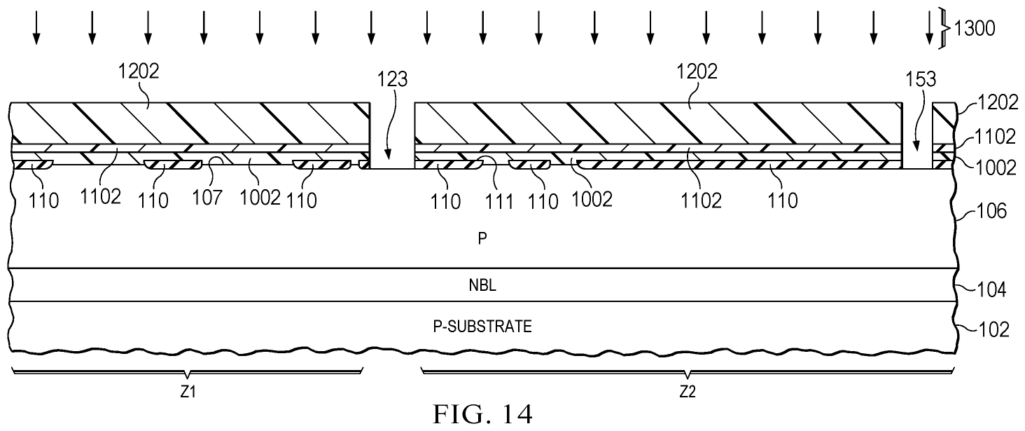

The method 200 continues at 212 in FIG. 2 with etching the exposed portions of the STI structure 110 to form initial portions of the deep trenches 123 and 153. FIGS. 13 and 14 show one example, in which a first etch process 1300 is performed using the trench etch mask 1002, 1102, 1202. FIG. 13 shows partial performance of the etch process 1300 forming the trench 123 partially into the portion of the STI structure 110 exposed by the trench etch mask 1002, 1102, 1202. FIG. 14 shows continued etching via the process 1300 to expose a portion of the top side 107 of the semiconductor surface layer 106 at the bottom of the partially formed trench 123. In one example, the first etch process 1300 is a fluorinated etch using carbon, fluorine, and hydrogen sources. In another example, the etch chemistry is carbon and fluorine only and no hydrogen. In one implementation, the first etch process 1300 is selective to the STI material using Ar/O₂/CF₄/CHF₃ and with or without one or more other fluorocarbons, and with or without N₂. In one example, the first etch process 1300 is performed at room temperature in a plasma etch reactor. In one implementation, an ash and clean operation is performed to strip off any remaining photo resist and clean the electronic device. In one example, the ash operation uses Ar/O₂/N₂/H₂/CF₄, either all or combinations thereof at a temperature of 100 ° C. or more. In one example, the clean operation is a dilute HF or industry standard cleaning chemistries in a single wafer tool or hood. In another implementation, the ash and clean operation is omitted.

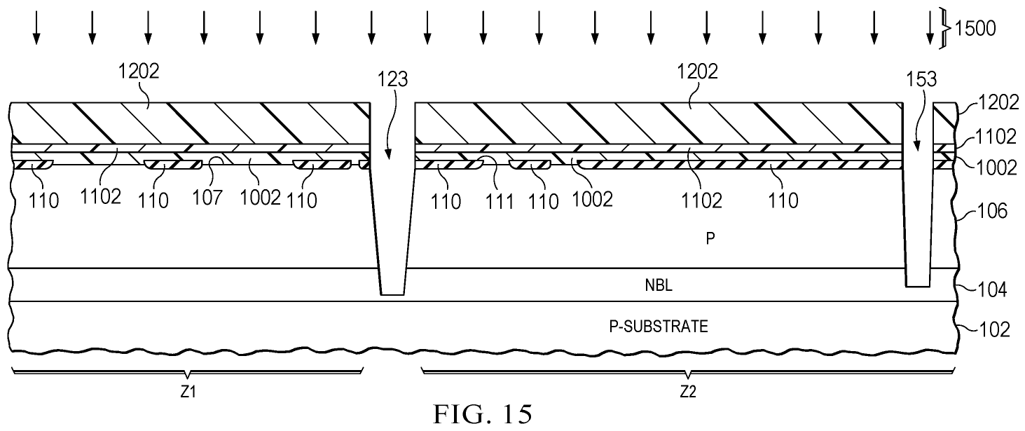

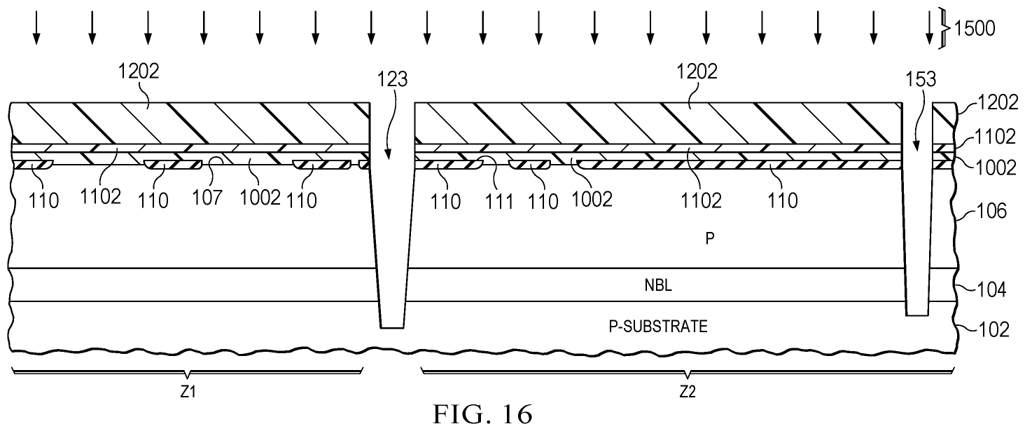

At 214 in FIG. 2, a second etch is performed using the trench etch mask 1002, 1102, 1202 to etch through the exposed portion of the semiconductor surface layer 106 and to expose first and second portions of the semiconductor substrate 102. In another implementation, the second etch process at 214 etches through the buried layer 104 and exposes a portion of the buried layer 104. FIGS. 15 and 16 show one example, in which a second etch process 1500 is performed using the trench etch mask 1002, 1102, 1202. FIG. 15 shows partial performance of the etch process 1500 that extends the trenches 123 and 153 into the portions of the semiconductor surface layer 106 exposed by the trench etch mask 1002, 1102, 1202. FIG. 16 shows continuation of the second etch process 1500 that etches through the remaining portions of the semiconductor surface layer 106 (e.g., and through the buried layer 104) and etches the trenches 123 and 153 into the semiconductor substrate 102 below the buried layer 104. In one example, the first etch process 1300 is performed in a first etching tool at 212, and the processed wafer is moved to a different etching tool for the second etch process 1500 at 214 in FIG. 2. In one example, the second etch process 1500 etches the trench 123 into the semiconductor surface layer 106 and into the semiconductor substrate 102 to a trench depth of 20 to 30 μm, such as about 26 μm, and stops in the semiconductor substrate 102 below the bottom of the buried layer 104 as shown in FIG. 16. In this or other examples, the narrower second trench 153 is etched by the process 1500 to a shallower trench depth due to the narrower opening in the trench etch mask 1002, one 1102, 1202. In one example, the second etch process 1500 uses a combination of SF6, oxygen, argon, and HDR, M02. In another implementation, the second etch process 1500 uses an Ar/SF₆/O₂/CF₄/HBr/N₂ etch chemistry. In other implementations, the second etch process 1500 uses a combination of all or some (e.g., two or more) of Ar/SF₆/O₂/CF₄/HBr/N₂. In one implementation, the second etch process 1500 is an anisotropic etch performed in a plasma reactor with source and bias radio frequency (RF) power.

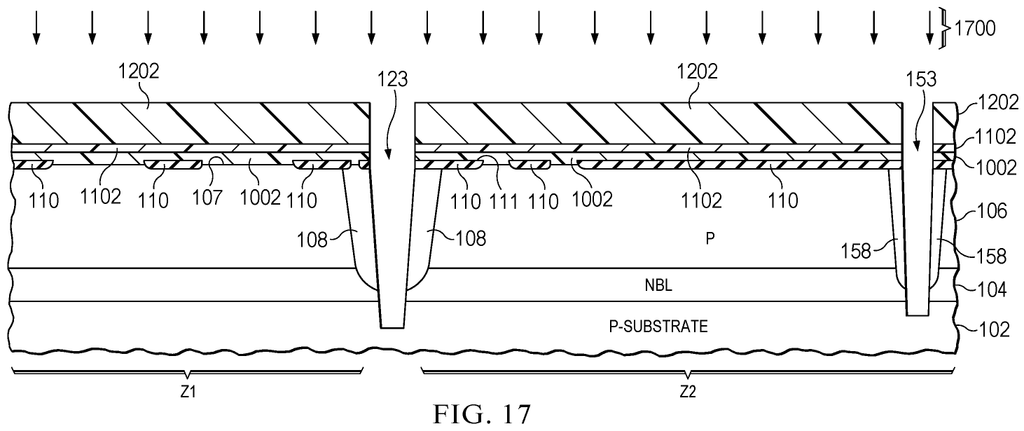

In the illustrated implementation, the method 200 continues at 216 with deep doped region implantation. In another implementation, such as for a self-aligned deep doped regions 108 and 158 and respective deep trenches 123 and 153, portions of the trenches 123 and 153 are etched into a previously formed second deep implanted region using the second etch process 1500 to expose the blanket implanted buried layer, and the trench sidewalls are then implanted using traditional beam line implanters, after which the second etch process 1500 is resumed to etch the rest of the trenches 123 and 153. At 216 in FIG. 2, the method 200 forms the deep doped regions 108 and 158 that include majority carrier dopants of the second conductivity type (e.g., N). FIG. 17 shows one example, in which an implantation process 1700 is performed using the trench etch mask 1002, 1102, 1202. The implantation process 1700 implants dopants of the second conductivity type (e.g., N in the illustrated example) into the exposed portions of the semiconductor surface layer 106 and the buried layer 104 to form the deep doped regions 108 and 158 extending from the semiconductor surface layer 106 and into to the buried layer 104.

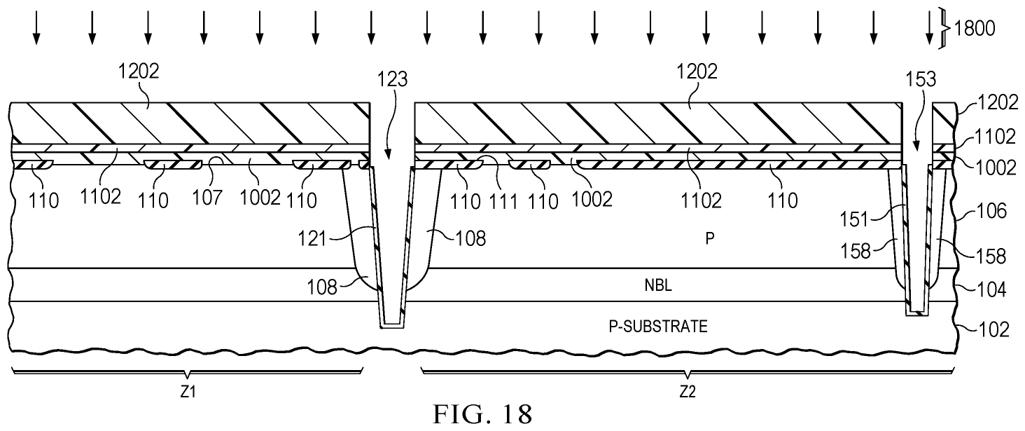

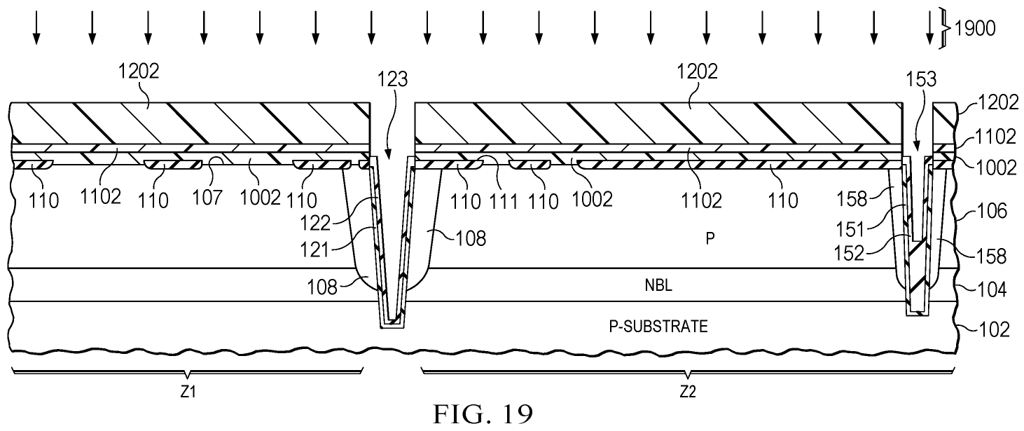

The method 200 continues at 218 in FIG. 2 with forming single or multi-layer trench liners in the trenches 123 and 153. The total thickness and composition of the trench liners are tailored according to a target breakdown voltage rating for the deep trench structures 120 and 150 in a given technology. In one example, the total thickness of the dielectric liners 121, 122 and 151, 152 is 500 to 600 nm. FIGS. 18 and 19 show one example that forms a bilayer oxide trench liners 121, 122 and 151, 152 as shown in FIG. 1 above. The dielectric liners 121, 122 and 151, 152 are formed along the sidewalls of the respective trenches 123 and 153 from the semiconductor surface layer 106 to the semiconductor substrate 102. In another implementation, such as where a blanket implant was used to form the buried layer 104, the dielectric liners 121, 122 and 151, 152 extend to the buried layer 104. In another example where a blanket implant was used to form the buried layer 104, the dielectric liners 121, 122 and 151, 152 extend to the buried layer 104 and beyond into the underlying semiconductor substrate 102 below the buried layer 104. The nominal layer thicknesses and composition of the trench liners 121, 122 and 151, 152 are adjustable and vary within manufacturing tolerances. In other example, more or fewer layers are used in forming the trench liners for the trenches 123 and 153. In the illustrated example, the liner 152 in the narrower trench 153 fills the trench 153 to a higher level than the dielectric liner 122 in the wider trench 123.

FIG. 18 shows one example, in which a process 1800 is performed that forms the first dielectric liners 121 and 151 on the respective trench sidewalls. The process 1800 in one example includes thermal growth in a furnace with an oxidizing interior environment using an O₂ source stream at a temperature of about 1050° C. to deposit or grow the first dielectric liners 121 and 151 to a thickness of 100 to 400 nm.

In FIG. 19, a deposition process 1900 is performed that deposits the second dielectric liners 122 and 152 as second oxides on the respective first dielectric liners 121 and 151. In one implementation, the deposition process 1900 is a sub-atmospheric pressure chemical vapor deposition (SA-CVD) process, for example, using O₂ and/or ozone (O₃) as a source gas to help catalyze the reaction, at a pressure between 13,300 Pa and 80,000 Pa, and a process temperature of about 300 to 500° C. In one example, the process 1900 deposits the second dielectric liners 122 and 152 as conformal layers both inside the trenches 123 and 153 along the first dielectric liners 121 and 151, as well as outside the trenches 123 and 153 and on the trench etch mask 1002, 1102, 1202 (not shown in FIG. 19).

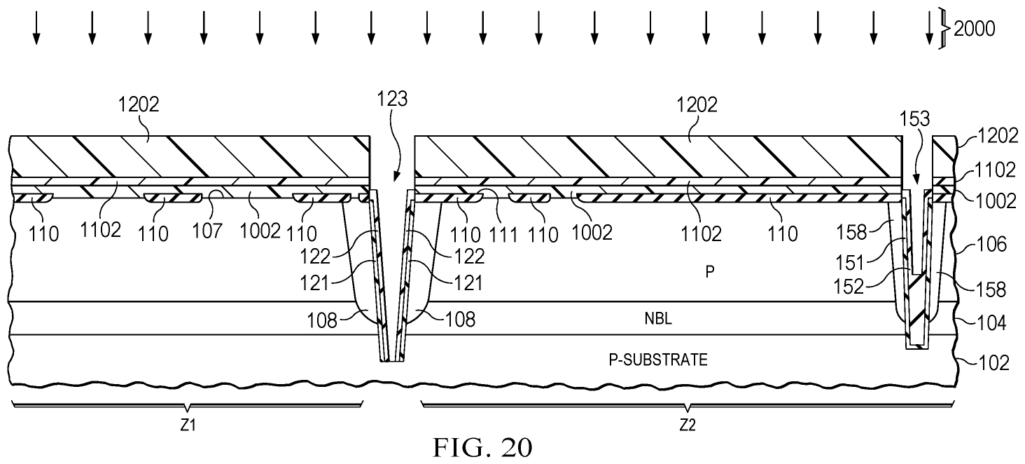

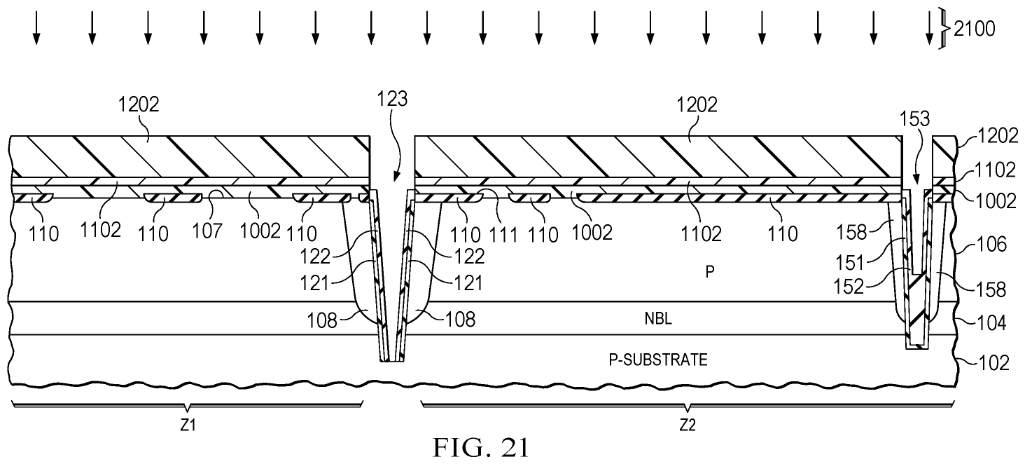

At 220 in FIG. 2, the method 200 continues with etching the dielectric liner 121, 122 of the first trench 123. FIG. 20 shows one example, in which a trench liner etch process 1800 is performed, such as an anisotropic plasma dry etch that is self-aligned etch without any additional mask. In one implementation, the etch process 2000 uses all or a combination of Ar/CF₄/CH₂F₂/CHF₃/N₂/O₂, and/or another fluorocarbon source at room temperature in a plasma reactor with RF sources and bias power for anisotropy. The etch process 2000 removes the dielectric liners 121 and 122 from the bottom of the trench 123 and exposes a portion of the semiconductor substrate 102. In one example, the device is cleaned after the trench bottom etch at 220. FIG. 21 shows one example, in which a cleaning process 2100 is performed that cleans the trench bottom. In one example, the cleaning process 2100 is a dilute HF or other low oxide loss cleaning operation performed in a single wafer processing tool or hood, such as SC1-SPOM, etc.

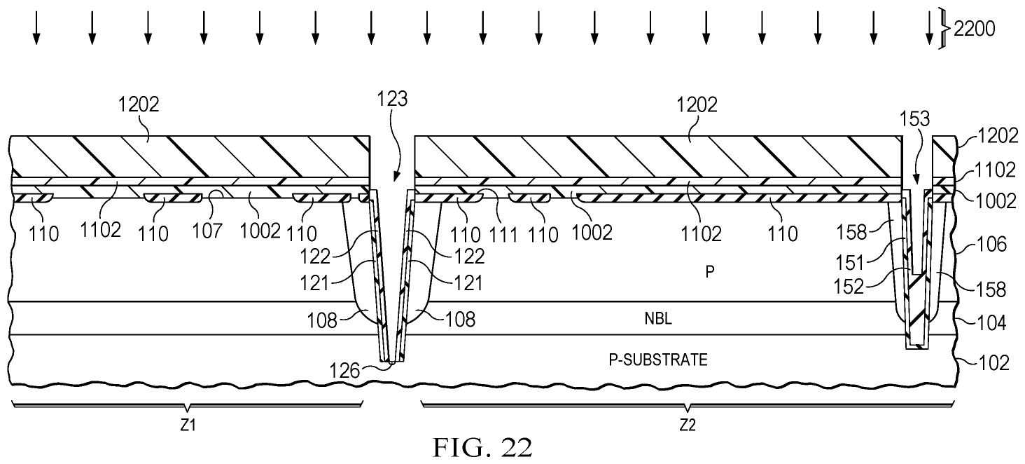

At 222 in FIG. 2, the method 200 continues with implanting the bottom of the trench 123 with majority carrier dopants of a first conductivity type (e.g., P in the illustrated example). FIG. 22 shows one example, in which a trench bottom implantation process 2200 is performed that implants boron or other majority carrier dopants of the first conductivity type into the implanted contact 126 (e.g., an implanted region) of the semiconductor substrate 102. The trench bottom implantation process 2200 enhances conductivity and passivates any damage to the interface of the underlying material of the semiconductor substrate 102 or buried layer material resulting from the trench bottom etch process 2000. No additional mask is required for the trench bottom implantation process 2000 since the trench etch mask 1002, 1102, 1202 prevents implantation outside the trench 123. In one example, the trench bottom implantation process 2200 is performed using a beam line implantation tool for zero-degree implantation of boron dopants at an implantation energy of 60 keV to provide a majority carrier concentration of 5E14 atoms/cm³ with four rotations of the wafer during implantation.

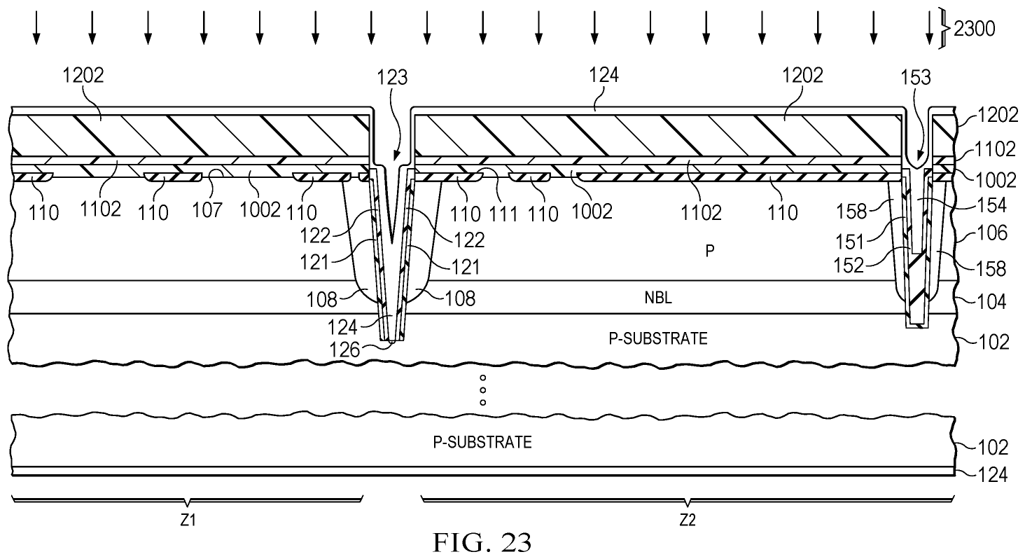

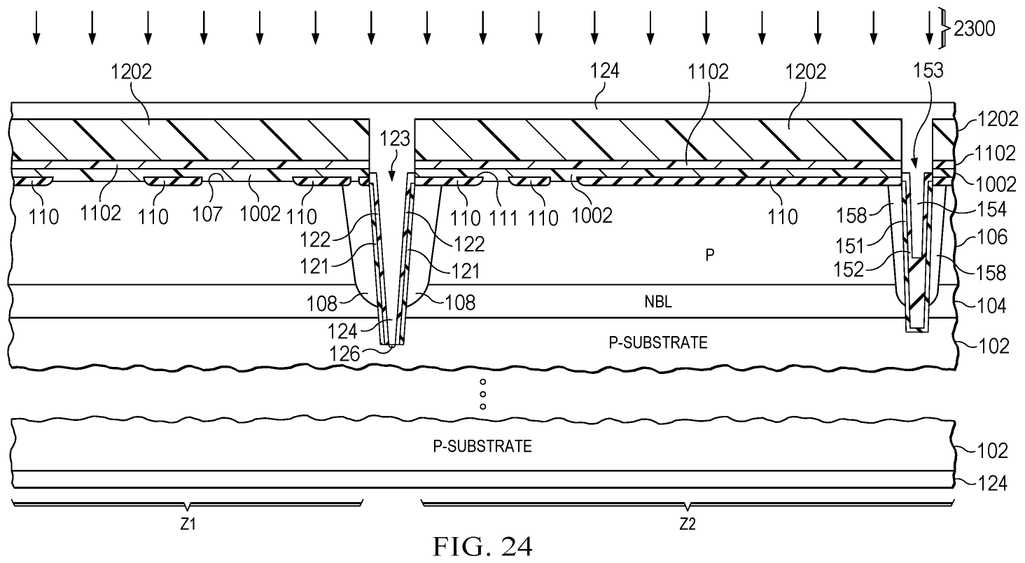

The method 200 in FIG. 2 also includes filling the trenches 123 and 153 with the polysilicon 124 at 224. FIGS. 23 and 24 show one example, in which a process 2300 is performed that forms the polysilicon 124, 154 in the trenches 123 and 153 and fills the trenches 123 and 153 to and beyond the top side 107 of the semiconductor surface layer 106, including on the trench etch mask 1002, 1102, 1202. The process 2300 in one example includes polysilicon growth with in-situ doping to form the doped polysilicon 124 with majority carrier dopants of the first conductivity type (e.g., P in the illustrated example). FIG. 23 shows partial completion of the trench fill deposition process 2300 that conformally starts to fill the trenches 123 and 153 while conformally covering the device with deposited polysilicon 124, 154 outside the trenches 123 and 153 and on the wafer bottom. FIG. 24 shows completion of the process 2300 with the trenches 123 and 153 filled with polysilicon 124, 154.

In one example, the deposition process 2300 includes in-situ doped polysilicon fill using BCl₃ as a dopant source gas for boron with silane as the Si source. In one implementation, the entire deposited polysilicon is doped in-situ. Another implementation deposits an in-situ doped thin layer and then deposits an undoped layer, followed by an anneal or high temperature drive to diffuse dopants throughout. In one example, the polysilicon deposition process 2300 is performed in a furnace at a process temperature of 500 to 700° C. In another example, the process 2300 deposits completely undoped polysilicon 124, 154 followed by an implant with N-type or P-type dopants using a suitable implantation process. In another example, a deposition (e.g., epitaxial growth) is performed and a separate implantation provides majority carrier dopants of the first conductivity type into the deposited polysilicon 124, 154 in the trenches 123 and 153, followed by a thermal anneal to drive the implanted dopants into the polysilicon 124, 154 in the filled trenches 123 and 153. In the illustrated example, the process 2300 forms the polysilicon 124, 154 in the trenches 123 and 153 along the respective dielectric liners 121, 122 and 151, 152 and the polysilicon 124, 154 also extends over the trench etch mask 1002, 1102, 1202 that remains on the STI structure 110.

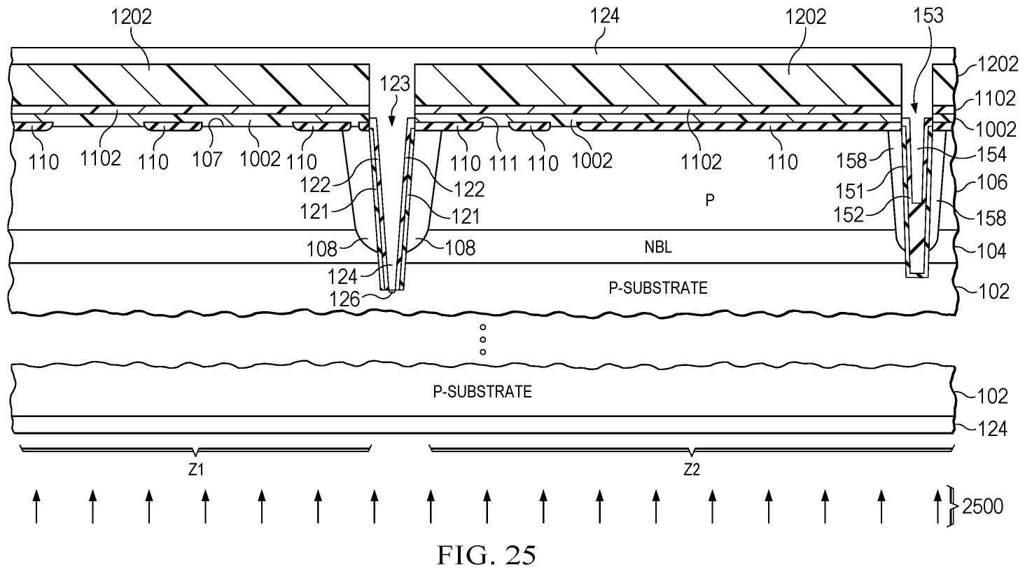

The method 200 continues at 226 in FIG. 2 with removing the deposited polysilicon from the wafer backside (e.g., from the bottom). FIG. 25 shows one example, in which a stripping process 2500 is performed that removes the polysilicon 124 from the back side of the semiconductor substrate 102. In one implementation, the back side poly strip process 2500 includes exposing the back side of the semiconductor substrate 102 to HF/nitric acid to provide high selectivity to SiO₂ and SiN using a wafer clean tool, such as SEZ, etc.

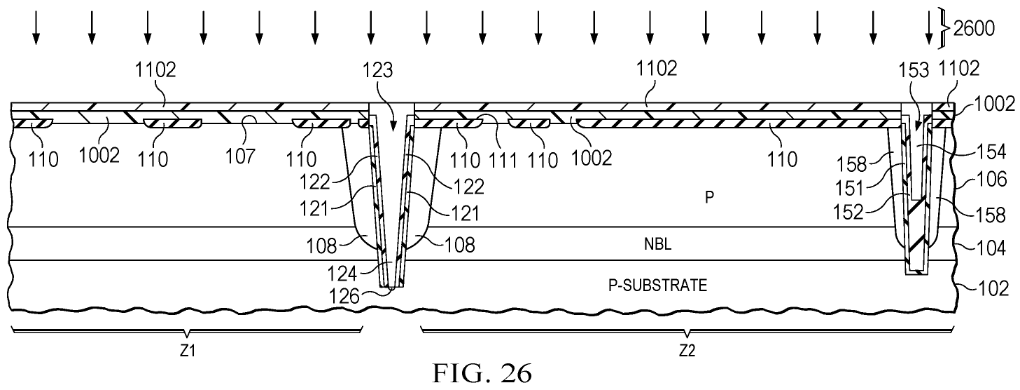

At 228 in FIG. 2, the method 200 also includes planarizing the front side of the wafer (e.g., the top side in the illustrated orientation). FIG. 26 shows one example, in which a chemical mechanical polishing (CMP) process 2600 is performed that planarizes the top side and sets the height of the top surfaces 125, 155 of the polysilicon 124, 154 in the respective trenches 123 and 153. In one example, the CMP process 2600 stops on or slightly into the trench etch mask 1102 of the multilayer trench etch mask. In one implementation, the CMP process 2600 is performed in a CMP tool using a process slurry, for example, a ceria slurry that has good selectivity to nitride, in which the polysilicon 124, 154 is polished with an endpoint to stops on the silicon dioxide, after which the silicon dioxide is polished stopping on the trench etch mask 1102. In one implementation, a further cleaning operation (not shown) is performed at 228, for example, using a non-HF solution to mitigate surface particle defects.

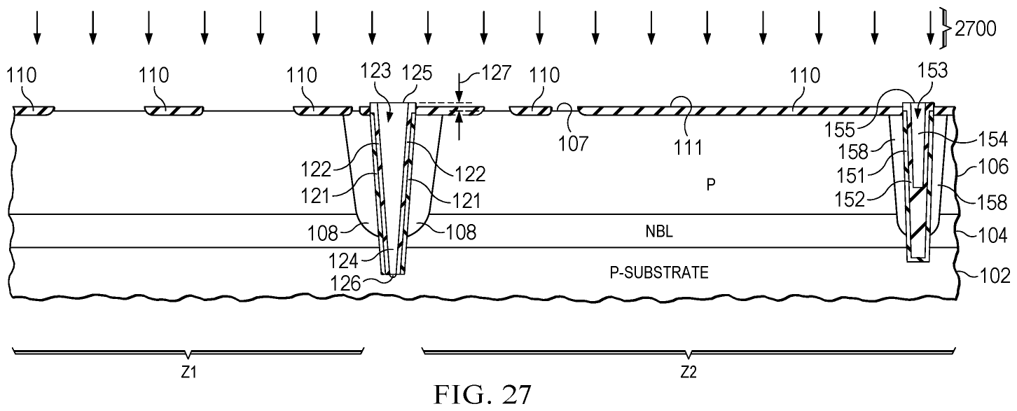

The method 200 continues at 230 in FIG. 2 with stripping our other process to remove the remaining trench etch mask remnants. FIG. 27 shows one example, in which a nitride strip process 2700 is performed that removes any remaining portions of the trench etch masks 1002 and 1102. In one example, the nitride strip process 2700 includes a hot phosphoric acid clean to etch SiN.

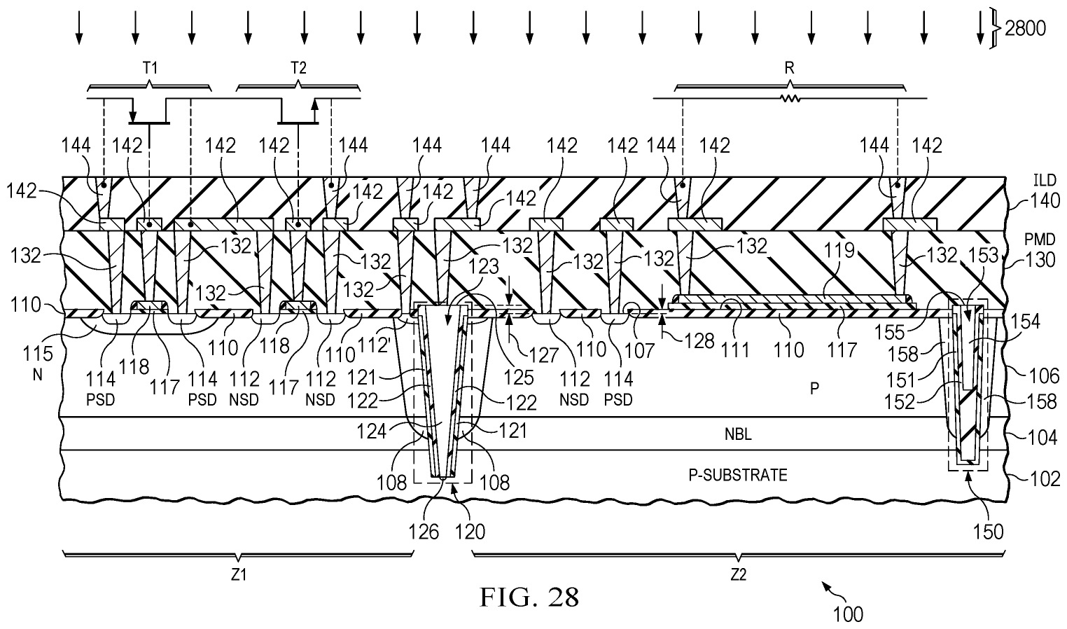

The method 200 also includes transistor fabrication and metallization at 232, beginning with gate polysilicon deposition and patterning, and includes formation of various circuit components, such as transistors, polysilicon capacitors and resistors, etc., as well as formation of a single or multilayer metallization structure. FIG. 28 shows one example, in which transistor and other circuit component fabrication processing 2800 is performed that forms circuit components, such as transistors T1 and T2, polysilicon capacitors and resistors (R), etc., as well as forming a single or multilayer metallization structure, where one or more of the circuit components (e.g., resistors, capacitors, or portions thereof) can be formed in one or more levels of the metallization structure.

At 234 in FIG. 2, the method 200 includes wafer probe testing, die separation or singulation to separate processed dies from the wafer structure, and packaging to produce packaged electronic devices. FIG. 1A shows the finished electronic device 100 that includes a package structure having the semiconductor die 160 enclosed in a molded package 162. In the illustrated example, the die 160 is mounted on the die attach pad 164, and conductive bond pads of the die 160 are electrically coupled to respective leads 166 via the conductive bond wires 168.

The example electronic device 100 and method 200 provide deep trench isolation solutions for any process flow in which a dielectric isolation layer such as the STI structure 110 is used for lateral device isolation or raised gate integration, etc., and incorporates deep trench isolation in the flow with shallow trench isolation processing before deep trench processing. The thickness and composition of the trench etch hard mask layer or layers (e.g., 1002, 1102, 1202 above) can be adjusted or tailored to enable enhanced dielectric breakdown performance in a cost-effective, robust and manufacturable deep trench isolation loop, with or without a self-aligned deep-n sinker and substrate contacts.

Modifications are possible in the described examples, and other implementations are possible, within the scope of the claims.

What is claimed is:

1. An electronic device, comprising:
a semiconductor substrate and a semiconductor surface layer having a first conductivity type, the semiconductor surface layer over the semiconductor substrate and having a top surface;
a buried layer having an opposite second conductivity type between the semiconductor surface layer and the semiconductor substrate;
a deep trench structure, including:
a trench that extends through the semiconductor surface layer and into the buried layer,
a dielectric liner on a sidewall of the trench from the semiconductor surface layer to the buried layer, and
polysilicon that extends on the dielectric liner and fills the trench to the side of the semiconductor surface layer; and
a shallow trench isolation structure that extends into the semiconductor surface layer, the shallow trench isolation structure in contact with the deep trench structure.

2. The electronic device of claim 1, further comprising a deep doped region having the second conductivity type, the deep doped region extending from the semiconductor surface layer to the buried layer.

3. The electronic device of claim 2, wherein the deep doped region surrounds the trench at a top surface of the semiconductor surface layer.

4. The electronic device of claim 3, wherein the polysilicon has the first conductivity type.

5. The electronic device of claim 3, wherein the trench extends through the buried layer and into the semiconductor substrate under the buried layer, and the polysilicon is connected to the semiconductor substrate by an implanted contact at a bottom of the trench.

6. The electronic device of claim 2, wherein the trench extends through the buried layer and into the semiconductor substrate under the buried layer.

7. The electronic device of claim 1, wherein the polysilicon has the first conductivity type.

8. The electronic device of claim 1, wherein the trench extends through the buried layer and into the semiconductor substrate under the buried layer.

9. The electronic device of claim 1, wherein the trench extends through the shallow trench isolation structure.

10. The electronic device of claim 1, comprising a transistor in or over the semiconductor surface layer and spaced apart from the deep trench structure.

11. The electronic device of claim 1, wherein the semiconductor surface layer has the first conductivity type.

12. An electronic device, comprising:
a semiconductor substrate having a first conductivity type;
a semiconductor surface layer over the semiconductor substrate and having the first conductivity type;
a buried layer having an opposite second conductivity type between the semiconductor surface layer and the semiconductor substrate;
a shallow trench isolation structure that extends into the semiconductor surface layer; and
a deep trench structure that extends through the shallow trench isolation structure, through the semiconductor surface layer, and into the buried layer, a top surface of the deep trench structure extending above a top surface of the shallow trench isolation structure.

13. The electronic device of claim 12, further comprising a deep doped region that extends from the semiconductor surface layer to the buried layer.

14. The electronic device of claim 13, wherein the deep doped region surrounds the deep trench structure at a top surface of the semiconductor surface layer.

15. The electronic device of claim 12, wherein the deep trench structure extends through the buried layer and into the semiconductor substrate under the buried layer.

16. The electronic device of claim 12, wherein the deep trench structure comprises:
a trench through the semiconductor surface layer and into the buried layer;
a dielectric liner on a sidewall of the trench from the semiconductor surface layer to the buried layer; and
polysilicon that extends on the dielectric liner and fills the trench to the side of the semiconductor surface layer.

17. A method of fabricating an electronic device, the method comprising:
forming a shallow trench isolation structure that extends into a semiconductor surface layer; and
forming a deep trench structure through the shallow trench isolation structure, through the semiconductor surface layer, and into a buried layer.

18. The method of claim 17, wherein forming the deep trench structure includes:
forming a trench through the shallow trench isolation structure, through the semiconductor surface layer, and into the buried layer;
forming a dielectric liner along a sidewall of the trench from the shallow trench isolation structure to the buried layer; and
filling the trench with poly silicon.

19. The method of claim 17, further comprising:
after forming the shallow trench isolation structure, forming a deep doped region that extends from a top surface of the semiconductor surface layer to the buried layer.

20. The method of claim 19, wherein the deep doped region surrounds the deep trench structure at a top surface of the semiconductor surface layer.
